(19) United States
(12) Patent Application Publication
(10) Pub. No.: US 2026/0120269 A1
(43) Pub. Date: Apr. 30, 2026

(54) MARK-BASED ALIGNMENT METHOD

(71) Applicant: THE INSTITUTE OF OPTICS AND ELECTRONICS, THE CHINESE ACADEMY OF SCIENCES, Chengdu, Sichuan (CN)

(72) Inventors: Xiangang Luo, Chengdu, Sichuan (CN); Zimo Yang, Chengdu, Sichuan (CN); Yan Tang, Chengdu, Sichuan (CN); Xin Zhou, Chengdu, Sichuan (CN); Jinhua Feng, Chengdu, Sichuan (CN); Yanqin Wang, Chengdu, Sichuan (CN); Yi Li, Chengdu, Sichuan (CN); Lixin Zhao, Chengdu, Sichuan (CN); Changtao Wang, Chengdu, Sichuan (CN)

(21) Appl. No.: 19/143,938

(22) PCT Filed: Dec. 29, 2022
(86) PCT No.: PCT/CN2022/143349

§ 371 Date: Jun. 27, 2025

(51) Int. Cl. G06T 7/00; G03F 1/42; G03F 9/00; G06F 18/25; G06T 7/12; G06T 7/73; H10P 72/50

(52) U.S. Cl. CPC G06T 7/001; G03F 1/42; G03F 9/7003; G03F 9/7076; G03F 9/7084; G03F 9/7092; G06F 18/25; G06T 7/12; G06T 7/74; H10P 72/57; G06T 2207/30148; G06T 2207/30204

(57) ABSTRACT

Alignment method of mask and substrate includes: summing grayscale values in mark image row by row or column by column respectively, to obtain first and second projection summation curves of rows and columns; calculating first mean value and standard deviation of center coordinates of mask mark, and second one of substrate mark based on above projection summation curves; extracting image contours of mark image, and adding horizontal or vertical processing window to image contours; extracting first contour grayscale curve of each row in horizontal processing window or second one of each column in vertical processing window; calculating third mean value and standard deviation of center coordinates of mask mark, and fourth one of substrate mark according to first or second contour grayscale curve; performing statistical fusion on four mean values and four standard deviations to obtain alignment deviation; and aligning mask and substrate according to alignment deviation.

### TECHNICAL FIELD

The present disclosure relates to the technical field of alignment detection, and in particular, to a mark alignment method combining a plurality of algorithms.

### BACKGROUND ART

In the manufacturing process of integrated circuits, patterns on a mask are transferred to a surface of a substrate through photochemical reactions during an exposure process. Therefore, exposure is often one of the most important processes in the entire manufacturing flow of integrated circuits. Modern integrated circuits generally adopt a three-dimensional multi-layer structure, which means that a plurality of pattern transfers are required. This process is called overlay. During the overlay, to ensure the functionality of a three-dimensional circuit structure, precise alignment between layers must be achieved; otherwise, the entire integrated circuit will fail.

After years of research and development, alignment technology has diversified. Currently, mainstream alignment methods include photometric alignment technology and diffraction-based alignment technology. For the photometric alignment technology, images of alignment marks pre-fabricated on a mask and a substrate are collected through an imaging lens assembly, and then an alignment deviation is calculated via digital image processing. This alignment method requires alignment marks with a simple structure, and is less affected by processes, substrate deformation, particles, etc., and thus it has advantages of a large measurement range and high stability. However, the accuracy is limited by a resolution of an image sensor and a magnification of the imaging lens assembly. Moreover, image processing algorithms used generally only provide a fixed result, and thus they are greatly affected by changes in algorithm parameter values and others. In terms of diffraction-based alignment technology, when an alignment light source illuminates gratings fabricated on the mask and the substrate, diffracted light from the two gratings interferes with each other, thereby forming interference light associated with a relative displacement between the mask and the substrate. By receiving this interference light with a sensor, an alignment deviation can be calculated. The accuracy of the diffraction-based alignment technology is only limited by a wavelength of the light source and a resolution of a measurement system, thus enabling very high precision. However, this method requires high-precision gratings as alignment marks, making mark fabrication difficult, and is also greatly affected by processes, substrate deformation, etc., thereby resulting in relatively poor stability. Moreover, due to the periodicity of the gratings, this method often has a small measurement range.

### SUMMARY

In view of the above technical problems, the present disclosure provides an alignment method of a mask and a substrate, which is used to at least partially solve the technical problems in the existing alignment technologies, such as being limited by the resolution of the image sensor and the magnification of the imaging lens assembly, the high processing difficulty of high-precision gratings, and poor alignment stability.

Based on this, a first aspect of the present disclosure provides an alignment method of a mask and a substrate, comprising: summing grayscale values in a mark image row by row or column by column respectively, so as to obtain first projection summation curves corresponding to rows and second projection summation curves corresponding to columns; calculating a first mean value and a first standard deviation of center coordinates of a mask mark, and a second mean value and a second standard deviation of center coordinates of a substrate mark based on the first projection summation curve corresponding to the rows and the second projection summation curve corresponding to the columns; extracting image contours of the mark image, and adding a horizontal processing window or a vertical processing window to the image contours; extracting a first contour grayscale curve of each row in the horizontal processing window or a second contour grayscale curve of each column in the vertical processing window; calculating a third mean value and a third standard deviation of center coordinates of the mask mark, and a fourth mean value and a fourth standard deviation of center coordinates of the substrate mark according to the first contour grayscale curve of each row or the second contour grayscale curve of each column; performing statistical fusion on the first mean value, the first standard deviation, the second mean value, the second standard deviation, the third mean value, the third standard deviation, the fourth mean value, and the fourth standard deviation to obtain an alignment deviation; and aligning the mask and the substrate according to the alignment deviation.

According to embodiments of the present disclosure, calculating the first mean value and the first standard deviation of the center coordinates of the mask mark and the second mean value and the second standard deviation of the center coordinates of the substrate mark based on the first projection summation curve corresponding to the rows and the second projection summation curve corresponding to the columns comprises: segmenting first peaks of the first projection summation curve with a first grayscale threshold, and segmenting second peaks of the second projection summation curve with a second grayscale threshold; calculating a first centroid for each peak above the first grayscale threshold on the first projection summation curve, and calculating a second centroid for each peak above the second grayscale threshold on the second projection summation curve; calculating a center coordinate of the mask mark and a center coordinate of the substrate mark according to the first centroid and the second centroid; changing magnitudes of the first grayscale threshold and the second grayscale threshold, and repeating the above operations to obtain the center coordinates of the mask mark and the center coordinates of the substrate mark; and calculating the first mean value and the first standard deviation according to the center coordinates of the mask mark, and calculating the second mean value and the second standard deviation according to the center coordinates of the substrate mark.

According to embodiments of the present disclosure, calculating the center coordinate of the mask mark and the center coordinate of the substrate mark according to the first centroid and the second centroid comprises: determining y-coordinates corresponding to peaks above the first grayscale threshold on the first projection summation curve according to the first centroid; determining x-coordinates corresponding to peaks above the second grayscale threshold on the second projection summation curve according to the second centroid; and calculating the center coordinate of the mask mark and the center coordinate of the substrate mark according to the y-coordinates corresponding to the peaks and the x-coordinates corresponding to the peaks. According to embodiments of the present disclosure, the first centroid or the second centroid is calculated according to:

$${g}_{k} ( i ) = \frac{{\sum }_{x 1}^{x 2} ( S ( x ) \cdot x )}{{\sum }_{x 1}^{x 2} S ( x )}$$

where x is a row number or column number of a pixel in the mark image, S(x) is a sum of grayscale values of pixels in an x-th row or an x-th column, k is a serial number of a peak above the first grayscale threshold on the first projection summation curve or a serial number of a peak above the second grayscale threshold on the second projection summation curve, x1 and x2 are respectively a start coordinate and an end coordinate of a k-th peak after segmenting, and i is a number of changes in the first grayscale threshold or a number of changes in the second grayscale threshold.

According to embodiments of the present disclosure, a number of peaks above the first grayscale threshold on the first projection summation curve and a number of peaks above the second grayscale threshold on the second projection summation curve are both 3. Calculating the center coordinate of the mask mark and the center coordinate of the substrate mark according to the y-coordinates corresponding to the peaks and the x-coordinates corresponding to the peaks comprises: calculating an x-coordinate xₚ₁(i) and a y-coordinate yₚ₁(i) of the center coordinate of the mask mark, and an x-coordinate x_{q1}(i) and a y-coordinate y_{q1}(i) of the center coordinate of the substrate mark according to:

$${x}_{p 1} ( i ) = ( {x}_{g 1 ( i )} + {x}_{g 3 ( i )} ) / 2$$

$${y}_{p 1} ( i ) = ( {y}_{g 1 ( i )} + {y}_{g 3 ( i )} ) / 2$$

$${x}_{q 1} ( i ) = {x}_{g 2 ( i )}$$

$${y}_{q 1} ( i ) = {y}_{g 2 ( i )}$$

where p represents the mask, q represents the substrate, x_{g1}(i), x_{g2}(i), and x_{g3}(i) are respectively the x-coordinates corresponding to the peaks above the second grayscale threshold on the second projection summation curve, and y_{g1}(i), y_{g2}(i), and y_{g3}(i) are respectively the y-coordinates corresponding to the peaks above the first grayscale threshold on the first projection summation curve.

According to embodiments of the present disclosure, calculating the third mean value and the third standard deviation of the center coordinates of the mask mark and the fourth mean value and the fourth standard deviation of the center coordinates of the substrate mark according to the first contour grayscale curve of each row or the second contour grayscale curve of each column comprises: performing interpolation on the first contour grayscale curve according to a first interpolation threshold or on the second contour grayscale curve according to a second interpolation threshold, so as to obtain coordinates of contour boundaries formed by the mask and the substrate on the first contour grayscale curve or on the second contour grayscale curve; calculating the center coordinates of the mask mark and the center coordinates of the substrate mark corresponding to rows or columns according to the coordinates of the contour boundaries formed by the mask and the substrate on the first contour grayscale curve or on the second contour grayscale curve; and calculating the third mean value, the third standard deviation, the fourth mean value, and the fourth standard deviation according to the center coordinates of the mask mark and the center coordinates of the substrate mark corresponding to the rows or columns.

According to embodiments of the present disclosure, a number of grayscale peaks on the first contour grayscale curve of each row or a number of grayscale peaks on the second contour grayscale curve of each column is 6. Calculating the center coordinates of the mask mark and the center coordinates of the substrate mark corresponding to the rows according to the coordinates of the contour boundaries formed by the mask and the substrate on the first contour grayscale curve comprises: calculating an x-coordinate xₚ₂(j) of a center coordinate of the mask mark and an x-coordinate x_{q2}(j) of a center coordinate of the substrate mark that correspond to a j-th row of pixels in the horizontal processing window according to:

$${x}_{p 2} ( j ) = ( {Cx}_{j , 1} + {Cx}_{j , 2} + {Cx}_{j , 5} + {Cx}_{j , 6} ) / 4$$

$${x}_{q 2} ( j ) = ( {Cx}_{j , 3} + {Cx}_{j , 4} ) / 2$$

and a y-coordinate yₚ₂(j) of the center coordinate of the mask mark and a y-coordinate y_{q2}(j) of the center coordinate of the substrate mark are a y-coordinate of the j-th row of pixels on the first contour grayscale curve, which is able to be obtained by converting a row number of the pixels into a coordinate value, where y represents a serial number of a grayscale peak, taking an integer from 1 to 6, and Cx_{j,v} represents an x-coordinate after interpolation of a y-th grayscale peak corresponding to the j-th row of pixels, where Cx_{j,v}=(C_{jl,v}+C_{jr,v})/2.

Calculating the center coordinates of the mask mark and the center coordinates of the substrate mark corresponding to the columns according to the coordinates of the contour boundaries formed by the mask and the substrate on the second contour grayscale curve comprises: calculating a y-coordinate yₚ₂(w) of a center coordinate of the mask mark and a y-coordinate y_{q2}(w) of a center coordinate of the substrate mark that correspond to a w-th column of pixels in the vertical processing window according to:

$${y}_{p 2} ( w ) = ( {Cy}_{w , 1} + {Cy}_{w , 2} + {Cy}_{w , 5} + {Cy}_{w , 6} ) / 4$$

$${y}_{q 2} ( w ) = ( {Cy}_{w , 3} + {Cy}_{w , 4} ) / 2 ,$$

and an x-coordinate xₚ₂(w) of the center coordinate of the mask mark and an x-coordinate x_{q2}(w) of the center coordinate of the substrate mark are an x-coordinate of the w-th column of pixels on the second contour grayscale curve, which is able to be obtained by converting a column number of the pixels into a coordinate value, where v represents a serial number of a grayscale peak, taking an integer from 1 to 6, and Cy_{w,v} represents a y-coordinate after interpolation of a v-th grayscale peak corresponding to the w-th column of pixels, where Cy_{w,v}=(C_{wl,v}+C_{wr,v})/2.

According to embodiments of the present disclosure, performing the statistical fusion on the first mean value, the first standard deviation, the second mean value, the second standard deviation, the third mean value, the third standard deviation, the fourth mean value, and the fourth standard deviation to obtain the alignment deviation comprises: calculating an accurate center coordinate of the mask mark according to the first mean value, the first standard deviation, the third mean value, and the third standard deviation based on a two-dimensional Gaussian distribution; calculating an accurate center coordinate of the substrate mark according to the second mean value, the second standard deviation, the fourth mean value, and the fourth standard deviation based on a two-dimensional Gaussian distribution; and calculating the alignment deviation according to accurate center coordinates of mask marks and accurate center coordinates of substrate marks.

According to embodiments of the present disclosure, the accurate center coordinate of the mask mark or the accurate center coordinate of the substrate mark is calculated according to:

$$( {x}^{*} , {y}^{*} ) = {u}^{*} ( x , y ) = u 1 + \frac{{σ1}^{2} ( x , y ) ( u 2 ( x , y ) - u 1 ( x , y ) )}{{σ1}^{2} ( x , y ) + {σ2}^{2} ( x , y )}$$

where [u1(x,y), σ1(x,y)] represents the two-dimensional Gaussian distribution corresponding to the first mean value and the first standard deviation or the two-dimensional Gaussian distribution corresponding to the second mean value and the second standard deviation, and [u2(x,y), σ2(x,y)] represents the two-dimensional Gaussian distribution corresponding to the third mean value and the third standard deviation or the two-dimensional Gaussian distribution corresponding to the fourth mean value and the fourth standard deviation.

According to embodiments of the present disclosure, calculating the alignment deviation according to the accurate center coordinates of the mask marks and the accurate center coordinates of the substrate marks comprises: calculating the alignment deviation according to:

$$Δ x = \frac{( {x}_{w 1}^{*} - {x}_{m 1}^{*} ) + ( {x}_{w 2}^{*} - {x}_{m 2}^{*} )}{2}$$

$$Δ y = \frac{( {y}_{w 1}^{*} - {y}_{m 1}^{*} ) + ( {y}_{w 2}^{*} - {y}_{m 2}^{*} )}{2}$$

$$Δθ = arctan \frac{( {y}_{w 1}^{*} - {y}_{m 1}^{*} ) - ( {y}_{w 2}^{*} - {y}_{m 2}^{*} )}{D}$$

where the mask and the substrate each have two alignment marks, accurate coordinates of the two alignment marks of the mask are respectively

$$( {x}_{m 1}^{*} , {y}_{m 1}^{*} ) , ( {x}_{m 2}^{*} , {y}_{m 2}^{*} ) ,$$

D is a distance between the two alignment marks of the mask, accurate coordinates of the two alignment marks of the substrate are respectively

$$( {x}_{w 1}^{*} , {y}_{w 1}^{*} ) , ( {x}_{w 2}^{*} , {y}_{w 2}^{*} ) ,$$

Δx is a horizontal distance deviation between the mask and the substrate, Δy is a vertical distance deviation between the mask and the substrate, and Δθ is a rotation angle deviation between the mask and the substrate.

Th alignment method of the mask and the substrate provided in the embodiments of the present disclosure has at least the following beneficial effects.

The grayscale summation is performed on the mark image row by row or column by column respectively in a projection based summation, a group of center coordinates of the mark are calculated based on the summation results. The contours of the mark image are interpolated, and another group of center coordinates of the mark are calculated based on the interpolation results. Then, the two groups of center coordinates of the mark are fused. In this way, the statistical characteristics of the center coordinates of the mark obtained under different parameters are fully considered, so that the calculated center coordinates of the mask mark and the substrate mark are more accurate, thereby making the calculated alignment deviation more accurate and improving the alignment accuracy of the mask and the substrate.

Further, by setting different grayscale thresholds to segment the grayscale summation curves multiple times, a plurality of groups of center coordinates of the mask mark and the substrate mark are calculated, and then the mean values are calculated. By calculating a plurality of groups of center coordinates of the mask mark and the substrate mark based on a plurality of processing windows, and then calculating the mean values, the calculation accuracy of center coordinates of the mask mark and the substrate mark is improved, and thus the alignment accuracy of the mask and the substrate is improved.

Further, the final center coordinates of the mask mark and the substrate mark are calculated based on the two-dimensional Gaussian distributions, which not only considers the mean values of the center coordinates of the mask mark and the substrate mark, but also considers the variances, so as to ensure the accuracy of the final coordinates.

In addition, this method is based on the photometric alignment measurement technology, and by improving its digital image processing method to calculate the alignment deviation, it not only maintains the advantages of existing photometric technology such as a wide measurement range and a simple structure, but also improves the measurement accuracy and the stability.

### BRIEF DESCRIPTION OF DRAWINGS

Through the following description of the embodiments of the present disclosure with reference to the drawings, the above and other objectives, features, and advantages of the present disclosure will become clearer. In the figures:

FIG. 1 schematically shows a flowchart of an alignment method of a mask and a substrate provided in embodiments of the present disclosure.

FIG. 2A schematically shows a shape diagram of alignment marks on a mask and a substrate provided in embodiments of the present disclosure.

FIG. 2B schematically shows a shape diagram of alignment marks collected by an image sensor provided in embodiments of the present disclosure.

FIG. 3 schematically shows a curve diagram of grayscale projection summation provided in embodiments of the present disclosure.

FIG. 4 schematically shows a flowchart of operation S102 provided in embodiments of the present disclosure.

FIG. 5 schematically shows a flowchart of operation S403 provided in embodiments of the present disclosure.

FIG. 6 schematically shows a windowed image contour of the mark image provided in embodiments of the present disclosure.

FIG. 7 schematically shows a first contour grayscale curve diagram provided in embodiments of the present disclosure.

FIG. 8 schematically shows a flowchart of operation S104 provided in embodiments of the present disclosure.

FIG. 9 schematically shows an interpolation principle diagram of a contour grayscale curve provided in embodiments of the present disclosure.

FIG. 10 schematically shows a flowchart of operation S105 provided in embodiments of the present disclosure.

### DETAILED DESCRIPTION OF EMBODIMENTS

To make the objectives, technical solutions, and advantages of the present disclosure clearer, the present disclosure is further described in detail below with reference to specific embodiments and the drawings. Obviously, the described embodiments are some of the embodiments of the present disclosure, rather than all of them. Based on the embodiments in the present disclosure, all other embodiments obtained by those of ordinary skill in the art without creative efforts shall fall within the protection scope of the present disclosure.

The terms used herein are only for describing specific embodiments and are not intended to limit the present disclosure. The terms such as “include” and “contain” used herein indicate the presence of the described feature(s), step(s), operation(s), and/or component(s), but do not exclude the presence or addition of one or more other features, steps, operations, or components.

In the present disclosure, unless otherwise clearly specified and limited, the terms such as “install”, “link”, “connect”, and “fix” should be interpreted broadly. For example, “connection” may be a fixed connection, a detachable connection, or an integral connection; may be a mechanical connection, an electrical connection, or a mutual communication connection; may be a direct connection, or an indirect connection through an intermediate medium; may be an internal communication between two elements, or an interaction relationship between two elements. For those of ordinary skill in the art, the specific meanings of the above terms in the present disclosure may be understood according to specific situations.

In the description of the present disclosure, it is necessary to understand that an orientation or positional relationship indicated by the term such as “vertical”, “length”, “circumferential”, “front”, “rear”, “left”, “right”, “top”, “bottom”, “inside”, “outside” is based on an orientation or positional relationship shown in the drawings, which is only for the convenience of describing the present disclosure and simplifying the description, rather than indicating or implying that the referred subsystem or element must have a specific orientation, be constructed and operated in a specific orientation, and thus cannot be understood as a limitation to the present disclosure.

Throughout the drawings, same elements are represented by same or similar reference numerals. Conventional structures or configurations will be omitted when they may cause confusion in understanding the present disclosure. Moreover, the shapes, sizes, and positional relationships of components in the drawings do not reflect their actual sizes, proportions, and actual positional relationships. In addition, in the claims, any reference sign between parentheses shall not be construed as limiting the claims.

Similarly, to simplify the present disclosure and help understand one or more of the various disclosed aspects, in the above description of the exemplary embodiments of the present disclosure, various features of the present disclosure are sometimes grouped together into a single embodiment, figure or description thereof. The descriptions referring to the terms such as “an embodiment”, “some embodiments”, “an example”, “a specific example”, or “some examples” mean that specific feature(s), structure(s), material(s), or characteristic(s) described in combination with the embodiment or example are included in at least one embodiment or example of the present disclosure. The schematic representations of the above terms in the description do not necessarily refer to the same embodiment(s) or example(s). Moreover, the described specific feature(s), structure(s), material(s), or characteristic(s) may be combined in any one or more embodiments or examples in an appropriate manner.

In addition, the terms such as “first” and “second” are only used for descriptive purposes, and cannot be understood as indicating or implying relative importance or implicitly specifying the quantity of the indicated technical features. Thus, a feature defined with “first” or “second” may explicitly or implicitly include one or more features. In the description of the present disclosure, “a plurality of” means at least two, such as two, three, etc., unless otherwise expressly and specifically defined.

An alignment method of a mask and a substrate provided in the present disclosure involves using an image sensor (charge coupled device, CCD camera) as an acquisition means to collect alignment marks on the mask and substrate through an imaging lens assembly, then using a digital image processing method to obtain statistical characteristics of alignment deviations, and fusing the statistical characteristics under different parameters to calculate the alignment deviations between the mask and substrate, thereby controlling a wafer stage to complete an alignment action.

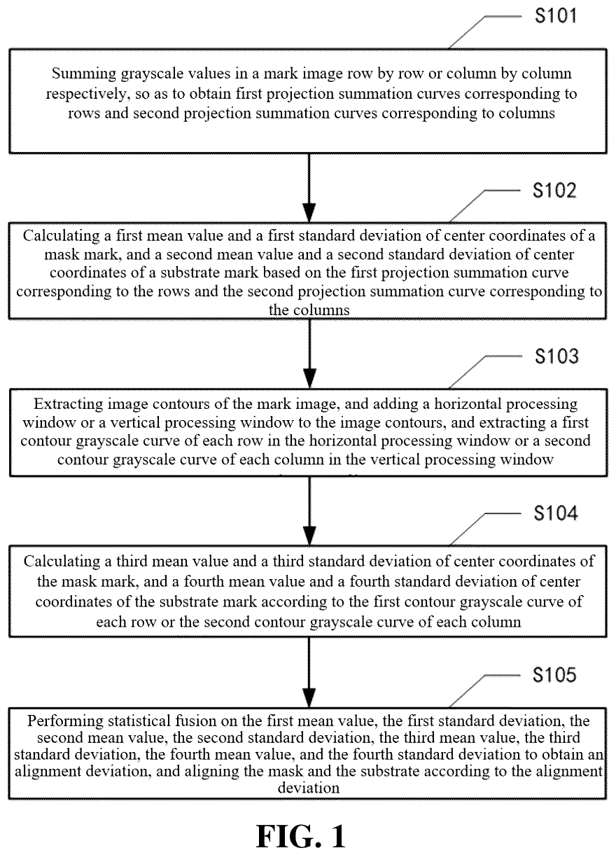

FIG. 1 schematically shows a flowchart of an alignment method of a mask and a substrate provided in embodiments of the present disclosure.

As shown in FIG. 1, the alignment method of the mask and the substrate may include, for example, operations S101 to S105.

In operation S101, grayscale values are summed in a mark image row by row or column by column respectively, so as to obtain first projection summation curves corresponding to rows and second projection summation curves corresponding to columns.

In operation S102, based on the first projection summation curve corresponding to the rows and the second projection summation curve corresponding to the columns, a first mean value and a first standard deviation of center coordinates of a mask mark, and a second mean value and a second standard deviation of center coordinates of a substrate mark are calculated.

In operation S103, image contours of the mark image are extracted, horizontal processing window(s) or vertical processing window(s) are added to the image contours, and a first contour grayscale curve of each row in the horizontal processing window(s) or a second contour grayscale curve of each column in the vertical processing window(s) is extracted.

In operation S104, according to the first contour grayscale curve of each row or the second contour grayscale curve of each column, a third mean value and a third standard deviation of center coordinates of the mask mark, and a fourth mean value and a fourth standard deviation of center coordinates of the substrate mark are calculated.

In operation S105, statistical fusion is performed on the first mean value, the first standard deviation, the second mean value, the second standard deviation, the third mean value, the third standard deviation, the fourth mean value, and the fourth standard deviation to obtain an alignment deviation, and the mask and the substrate are aligned according to the alignment deviation.

It should be noted that operations S101 to S104 are not intended to strictly limit an execution order of the alignment method in the embodiments of the present disclosure. Operations S101 to S102 may be executed first, followed by operations S103 to S104; operations S103 to S104 may be performed first, followed by operations S101 to S102; or operations S101 to S102 and operations S103 to S104 may be performed simultaneously.

Exemplarily, an image sensor may be used to collect the alignment marks on the mask and substrate to obtain the mark image with a size of M×N, where M indicates that there are M pixels in a vertical direction, and N indicates that there are N pixels in a horizontal direction.

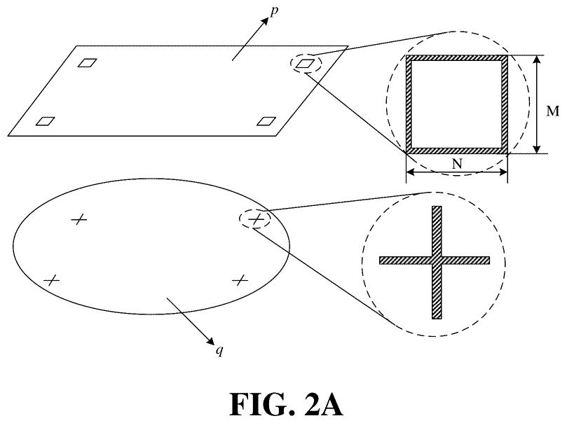

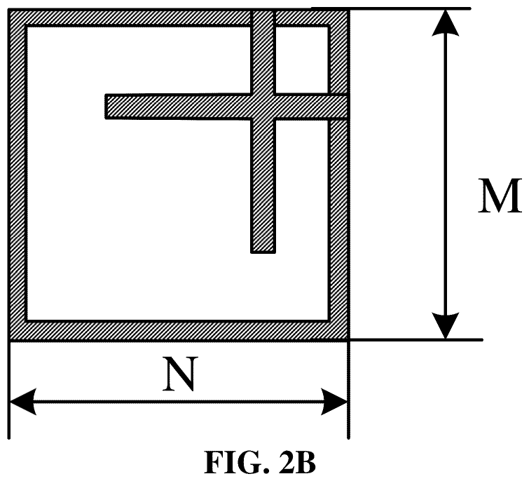

FIG. 2A schematically shows a shape diagram of alignment marks on a mask and a substrate provided in embodiments of the present disclosure. FIG. 2B schematically shows a shape diagram of alignment marks collected by an image sensor provided in embodiments of the present disclosure.

As shown in FIGS. 2A to 2B, the alignment mark on the mask may be a square alignment mark, and the alignment mark on the substrate may be a cross alignment mark. The alignment of the mask and substrate may be understood as the cross alignment mark being centered in the square alignment mark.

Exemplarily, the grayscale summation is performed on the mark image row by row and column by column respectively to obtain the projection summation curves S. A grayscale value corresponding to a pixel in an m-th row and an n-th column of the mark image is I(m, n), and grayscale summation formulas for the m-th row and n-th column are:

$${S}_{row} ( m ) = {\sum }_{n = 1}^{N} I ( m , n ) ( m = 1 , 2 , … , M )$$

$${S}_{col} ( n ) = {\sum }_{m = 1}^{M} I ( m , n ) ( n = 1 , 2 , … , N )$$

where S_{row}(m) is a sum of grayscale values corresponding to pixels in the m-th row, S_{col}(n) is a sum of grayscale values corresponding to pixels in the n-th column, the subscript “row” represents row, and the subscript “col” represents column.

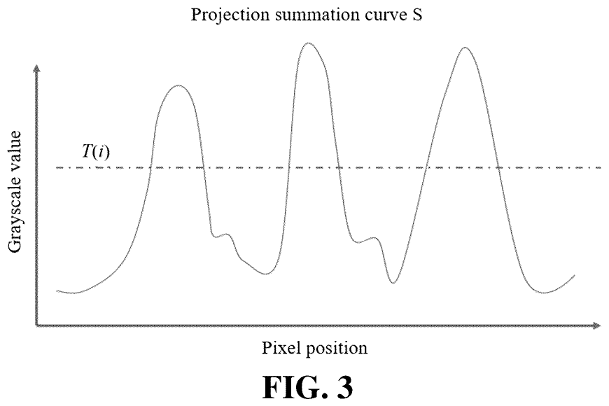

FIG. 3 schematically shows a curve diagram of grayscale projection summation provided in embodiments of the present disclosure.

As shown in FIG. 3, if an x-coordinate in FIG. 3 is m=1, 2, . . . , M, a y-coordinate is S_{row}(m); if the x-coordinate is n=1, 2, . . . , N, the y-coordinate is S_{col}(n).

According to the embodiments of the present disclosure, after the projection summation curve S corresponding to the rows or columns is obtained, a threshold segmenting method is used to perform peak segmenting on the first projection summation curve and the second projection summation curve, and then the first mean value and the first standard deviation of the center coordinates of the mask mark, and the second mean value and the second standard deviation of the center coordinates of the substrate mark are calculated based on segmenting results.

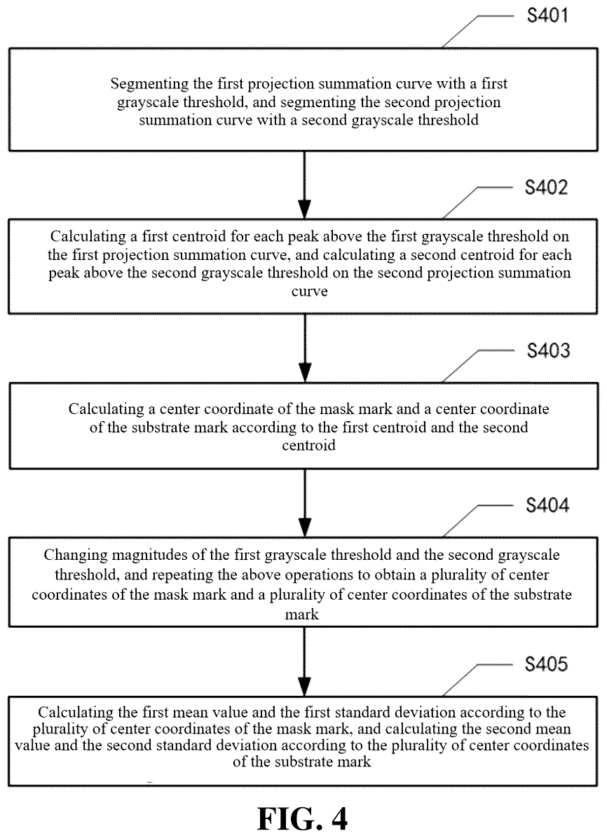

FIG. 4 schematically shows a flowchart of operation S102 provided in embodiments of the present disclosure.

As shown in FIG. 4, operation S102 of calculating the first mean value and the first standard deviation of the center coordinates of the mask mark and the second mean value and the second standard deviation of the center coordinates of the substrate mark may include operations S401 to S405.

In operation S401, segmenting the first projection summation curve with a first grayscale threshold, and segmenting the second projection summation curve with a second grayscale threshold.

In operation S402, a first centroid is calculated for each peak above the first grayscale threshold on the first projection summation curve, and a second centroid is calculated for each peak above the second grayscale threshold on the second projection summation curve.

In operation S403, a center coordinate of the mask mark and a center coordinate of the substrate mark are calculated according to the first centroid and the second centroid.

In operation S404, magnitudes of the first grayscale threshold and the second grayscale threshold are changed, and the above operations are repeated to obtain a plurality of center coordinates of the mask mark and a plurality of center coordinates of the substrate mark.

In operation S405, the first mean value and the first standard deviation are calculated according to the plurality of center coordinates of the mask mark, and the second mean value and the second standard deviation are calculated according to the plurality of center coordinates of the substrate mark.

Exemplarily, an initial grayscale threshold T(0) is selected, then an initial first grayscale threshold corresponding to the first projection summation curve is T_{row}(0)=(max(S_{row}(m))+min(S_{row}(m)))/2, and an initial second grayscale threshold corresponding to the second projection summation curve is T_{col}(0)=(max(S_{col}(n))+min(S_{col}(n)))/2.

To improve a calculation accuracy of a center coordinate of a mark, the magnitude of the first grayscale threshold may be changed multiple times to segment the first projection summation curve and the second projection summation curve. A grayscale threshold for an i-th threshold segmenting may be denoted as T(i), then the first grayscale threshold corresponding to the first projection summation curve is T_{row}(i), and the second grayscale threshold corresponding to the second projection summation curve is T_{col}(i). For each segmenting, a group of center coordinates of the mask mark and the substrate mark may be calculated correspondingly.

During the threshold segmenting process, it is necessary to determine whether a number i of segments reaches a set value a. After the number i of segmenting s reaches the set value a, based on a groups of center coordinates of the mask mark and the substrate mark, the first mean value, the first standard deviation, the second mean value, and the second standard deviation corresponding to the a groups of center coordinates of the mask mark and the substrate mark may be calculated. When the number i of segments does not reach the set value a, the first grayscale threshold and the second grayscale threshold continue to be changed to segment the first projection summation curve and the second projection summation curve, and the center coordinates of the mask mark and the substrate mark are calculated.

In the embodiments of the present disclosure, the first centroid or the second centroid gₖ(i) may be calculated according to:

$${g}_{k} ( i ) = \frac{{\sum }_{x 1}^{x 2} ( S ( x ) \cdot x )}{{\sum }_{x 1}^{x 2} S ( x )}$$

where x is a row number or column number of a pixel in the mark image, S(x) is a sum of grayscale values of pixels in an x-th row or an x-th column, k is a serial number of a peak on the first projection summation curve whose peak value exceeds the first grayscale threshold or a serial number of a peak above the second grayscale threshold on the second projection summation curve, x1 and x2 are respectively a start coordinate and an end coordinate of a k-th peak after segmenting, and i is a number of changes in the first grayscale threshold or a number of changes in the second grayscale threshold, i.e., the number of times of segmenting.

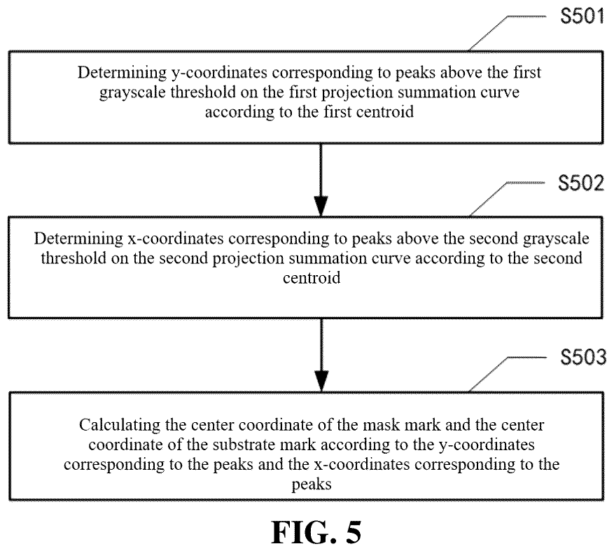

FIG. 5 schematically shows a flowchart of operation S403 provided in embodiments of the present disclosure.

As shown in FIG. 5, operation S403 of calculating the center coordinate of the mask mark and the center coordinate of the substrate mark according to the first centroid and the second centroid may include operations S501 to S503.

In operation S501, y-coordinates corresponding to peaks above the first grayscale threshold on the first projection summation curve are determined according to the first centroid.

In operation S502, x-coordinates corresponding to peaks above the second grayscale threshold on the second projection summation curve are determined according to the second centroid.

In operation S503, the center coordinate of the mask mark and the center coordinate of the substrate mark are calculated according to the y-coordinates corresponding to the peaks and the x-coordinates corresponding to the peaks.

Exemplarily, referring to FIG. 3 again, after each segmenting of the first projection summation curve with the first grayscale threshold and the second projection summation curve with the second grayscale threshold, three peak values above the first grayscale threshold and three peak values above the second grayscale threshold are retained. That is, an extreme value Tₘₐₓ of T(i) should be less than a third highest peak value in the projection summation curve S, i.e., T(i) is between T(0) and the third highest peak value. After an i-th cycle, a segmenting threshold T(i+1) for an (i+1)-th time is:

$$T ( i + 1 ) = T ( i ) + \frac{{T}_{max} - T ( 0 )}{a}$$

In the above calculation formula of gₖ(i), when x is the row number of the pixel in the mark image, i.e., x is m=1, 2, . . . , M, gₖ(i) represents the y-coordinates of the three peaks g₁(i), g₂(i), and g₃(i) corresponding to the first projection summation curve, denoted as y_{g1}(i), y_{g2}(i), and y_{g3}(i); when x is the column number of the pixel in the mark image, i.e., x is n=1, 2, . . . , N, gₖ(i) represents the x-coordinates of the three peaks g₁(i), g₂(i), and g₃(i) corresponding to the second projection summation curve, denoted as x_{g1}(i), x_{g2}(i), and x_{g3}(i).

Thus, an x-coordinate xₚ₁(i) and a y-coordinate yₚ₁(i) of the center coordinate of the mask mark, and an x-coordinate x_{q1}(i) and a y-coordinate y_{q1}(i) of the center coordinate of the substrate mark may be calculated according to:

$${x}_{p 1} ( i ) = ( {x}_{g 1 ( i )} + {x}_{g 3 ( i )} ) / 2$$

$${y}_{p 1} ( i ) = ( {y}_{g 1 ( i )} + {y}_{g 3 ( i )} ) / 2$$

$${x}_{q 1} ( i ) = {x}_{g 2 ( i )}$$

$${y}_{q 1} ( i ) = {y}_{g 2 ( i )}$$

where p represents the mask, q represents the substrate, x_{g1}(i), x_{g2}(i), and x_{g3}(i) are respectively the x-coordinates corresponding to the peaks above the second grayscale threshold on the second projection summation curve, and y_{g1}(i), y_{g2}(i), and y_{g3}(i) are respectively the y-coordinates corresponding to the peaks above the first grayscale threshold on the first projection summation curve.

After a times of segmenting with the first grayscale threshold T(i), the a groups of xₚ₁(i) and yₚ₁(i), and x_{q1}(i) and y_{q1}(i) of the center coordinates of the mask mark may be calculated, a center coordinates of the mask mark may be denoted as:

$$[ {x}_{p 1} ( 1 ) , {y}_{p 1} ( 1 ) ] , [ {x}_{p 1} ( 2 ) , {y}_{p 1} ( 2 ) ] , … [ {x}_{p 1} ( a ) , {y}_{p 1} ( a ) ] ,$$

and a center coordinates of the substrate mark may be denoted as:

$$[ {x}_{q 1} ( 1 ) , {y}_{q 1} ( 1 ) ] , [ {x}_{q 1} ( 2 ) , {y}_{q 1} ( 2 ) ] , … [ {x}_{q 1} ( a ) , {y}_{q 1} ( a ) ] .$$

A mean value and a variance of the above a center coordinates of the mask mark are respectively calculated to obtain the first mean value (x̅ₚ̅₁̅, y̅ₚ̅₁̅) and the first standard deviation (σₚₓ₁, σ_{py1}). A mean value and a variance of the a center coordinates of the substrate mark are respectively calculated to obtain the second mean value (x̅_̅{̅q̅1̅}̅, y̅_̅{̅q̅1̅}̅) and the second standard deviation (σ_{qx1}, σ_{qy1}).

Based on the above operations, the statistical characteristics of the center coordinates of the marks under the grayscale summation curves are acquired.

According to the embodiments of the present disclosure, a process of extracting the first contour grayscale curve and the second contour grayscale curve in operation S103 may be as follows.

High-pass filtering is performed on the mark image to extract high-frequency information, i.e., to retain the image contours and remove the background and filling to obtain a image contour. Then, according to the known mark size information and the results of the projection summation algorithm, processing window(s) are added to the image contour to remove redundant information such as the background.

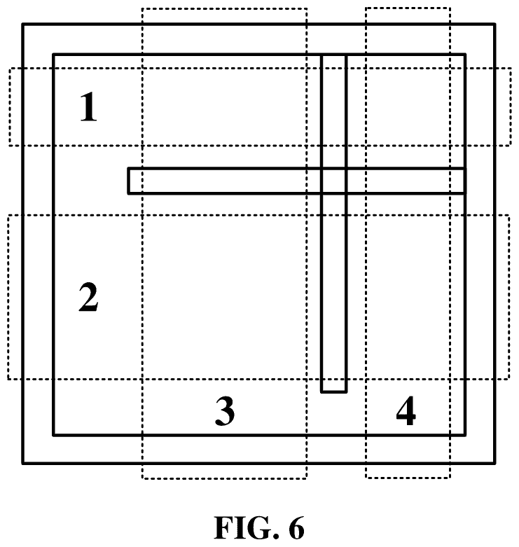

FIG. 6 schematically shows a image contour after windows are added provided in embodiments of the present disclosure.

As shown in FIG. 6, horizontal processing windows or vertical processing windows are added to the image contours. As shown by the dashed boxes in the figure, Labels 1 and 2 denote the horizontal processing windows, and Labels 3 and 4 denote the vertical processing windows.

For each horizontal processing window, contours in the horizontal processing window are extracted row by row to obtain the first contour grayscale curve. For each vertical processing window, contours in the vertical processing window are extracted column by column to obtain the second contour grayscale curve.

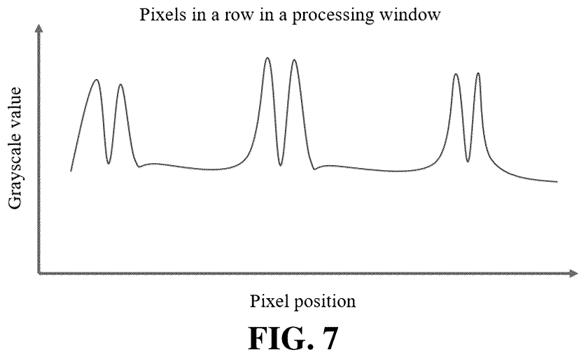

FIG. 7 schematically shows a first contour grayscale curve diagram provided in embodiments of the present disclosure.

As shown in FIG. 7, in each row, each contour forms a grayscale peak, and there are six grayscale peaks G_{j,1} to G_{j,6} on the contour grayscale curve of each row. Based on the first contour grayscale curve of each row, a center coordinate of the mask mark and a center coordinate of the substrate mark may be calculated. A specific calculation method is described below.

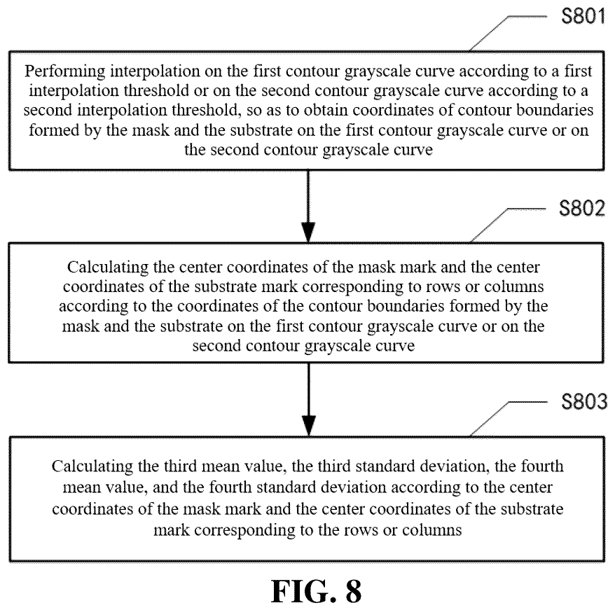

FIG. 8 schematically shows a flowchart of operation S104 provided in embodiments of the present disclosure.

As shown in FIG. 8, operation S104 of calculating the third mean value and the third standard deviation of the center coordinates of the mask mark and the fourth mean value and the fourth standard deviation of the center coordinates of the substrate mark may include operations S801 to S803.

In operation S801, interpolation is performed on the first contour grayscale curve according to a first interpolation threshold or on the second contour grayscale curve according to a second interpolation threshold, so as to obtain coordinates of contour boundaries formed by the mask and the substrate on the first contour grayscale curve or on the second contour grayscale curve.

In operation S802, according to the coordinates of the contour boundaries formed by the mask and the substrate on the first contour grayscale curve or on the second contour grayscale curve, the center coordinates of the mask mark and the center coordinates of the substrate mark corresponding to rows or columns are calculated.

In operation S803, according to the center coordinates of the mask mark and the center coordinates of the substrate mark corresponding to the rows or columns, the third mean value, the third standard deviation, the fourth mean value, and the fourth standard deviation are calculated.

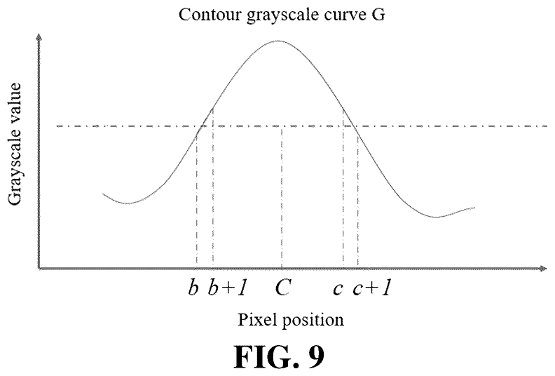

FIG. 9 schematically shows an interpolation principle diagram of a contour grayscale curve provided in embodiments of the present disclosure.

Exemplarily, as shown in FIG. 9, illustrated with a horizontal processing window, the first interpolation threshold is set to be Q(j), and G_{j,v} is a first contour grayscale curve of a v-th contour grayscale peak in a j-th row of pixels near Q (j) in the horizontal processing window. Interpolation points [b, Gⱼ(b)], [b+1, Gⱼ(b+1)] and [c, Gⱼ(c)], [c+1, Gⱼ(c+1)] near Q(j) are selected. Local linearization is performed on left and right sides of the r-th contour grayscale peak in the j-th row of pixels to obtain left and right borders of a contour, and details are as follows:

$${C}_{jl , v} = \frac{Q ( j ) - G ( b )}{G ( b + 1 ) - G ( b )} + b$$

$${C}_{jr , v} = \frac{Q ( j ) - G ( c )}{G ( c + 1 ) - G ( c )} + c$$

where C_{jl,v} represents the left border of the r-th contour grayscale peak in the horizontal processing window, C_{jr,v} represents the right border of the v-th contour grayscale peak in the horizontal processing window, the subscript “l” represents the left border, the subscript “r” represents the right border, and v=1, 2, 3, 4, 5, 6.

Based on the contour boundaries, an x-coordinate xₚ₂(j) of a center coordinate of the mask mark and an x-coordinate x_{q2}(j) of a center coordinate of the substrate mark that correspond to the j-th row of pixels in the horizontal processing window may be calculated according to:

$${x}_{p 2} ( j ) = ( {Cx}_{j , 1} + {Cx}_{j , 2} + {Cx}_{j , 5} + {Cx}_{j , 6} ) / 4$$

$${x}_{q 2} ( j ) = ( {Cx}_{j , 3} + {Cx}_{j , 4} ) / 2$$

and a y-coordinate yₚ₂(j) of the center coordinate of the mask mark and a y-coordinate y_{q2}(j) of the center coordinate of the substrate mark are a y-coordinate of the j-th row of pixels on the first contour grayscale curve, which may be obtained by converting the row number of the pixels into a coordinate value, where v represents a serial number of a grayscale peak, taking an integer from 1 to 6, and Cx_{j,v} represents an x-coordinate after interpolation of a v-th grayscale peak corresponding to the j-th row of pixels, where Cx_{j,v}=(C_{jl,v}+C_{jr,v})/2.

Similarly, in a vertical processing window, based on the contour boundaries, a y-coordinate yₚ₂(w) of a center coordinate of the mask mark and a y-coordinate y_{q2}(w) of a center coordinate of the substrate mark that correspond to a w-th column of pixels in the vertical processing window may be calculated according to:

$${y}_{p 2} ( w ) = ( {Cy}_{w , 1} + {Cy}_{w , 2} + {Cy}_{w , 5} + {Cy}_{w , 6} ) / 4$$

$${y}_{q 2} ( w ) = ( {Cy}_{w , 3} + {Cy}_{w , 4} ) / 2$$

and an x-coordinate xₚ₂(w) of the center coordinate of the mask mark and an x-coordinate x_{q2}(w) of the center coordinate of the substrate mark are an x-coordinate of the w-th column of pixels on the second contour grayscale curve, which may be obtained by converting a column number of the pixels into a coordinate value, where y represents a serial number of a grayscale peak, taking an integer from 1 to 6, and Cy_{w,v} represents a y-coordinate after interpolation of a r-th grayscale peak corresponding to the w-th column of pixels, where Cy_{w,v}=(C_{wl,v}+C_{wr,v})/2.

It should be understood that the principle of the vertical processing window is similar to the horizontal processing operations.

After all the horizontal and vertical processing windows are processed, d groups of xₚ₂(j), yₚ₂(j), x_{q2}(j), and y_{q2}(j) may be calculated, where d represents the number of all rows or columns in a window, and d center coordinates of the mask mark may be denoted as:

$$[ {x}_{p 2} ( 1 ) , {y}_{p 2} ( 1 ) ] , [ {x}_{p 2} ( 2 ) , {y}_{p 2} ( 2 ) ] , … [ {x}_{p 2} ( d ) , {y}_{p 2} ( d ) ] ,$$

and d center coordinates of the substrate mark may be denoted as:

$$[ {x}_{q 2} ( 1 ) , {y}_{q 2} ( 1 ) ] , [ {x}_{q 2} ( 2 ) , {y}_{q 2} ( 2 ) ] , … [ {x}_{q 2} ( d ) , {y}_{q 2} ( d ) ] .$$

A mean value and a variance of the above d center coordinates of the mask mark are respectively calculated to obtain the third mean value (x̅ₚ̅₂̅, y̅ₚ̅₂̅) and the third standard deviation (σₚₓ₂, σ_{py2}). A mean value and a variance of the d center coordinates of the substrate mark are respectively calculated to obtain the fourth mean value (x̅_̅{̅q̅2̅}̅, y̅_̅{̅q̅2̅}̅) and the fourth standard deviation (σ_{qx2}, σ_{gy2}).

Based on the above operations, the statistical characteristics of the center coordinates of the marks under the contour curves are acquired.

Next, by fusing the statistical characteristics of the center coordinates of the marks under the grayscale summation curves and the contour curves, an accurate center coordinate of the mask mark and an accurate center coordinate of the substrate mark may be obtained, thereby calculating the alignment deviation.

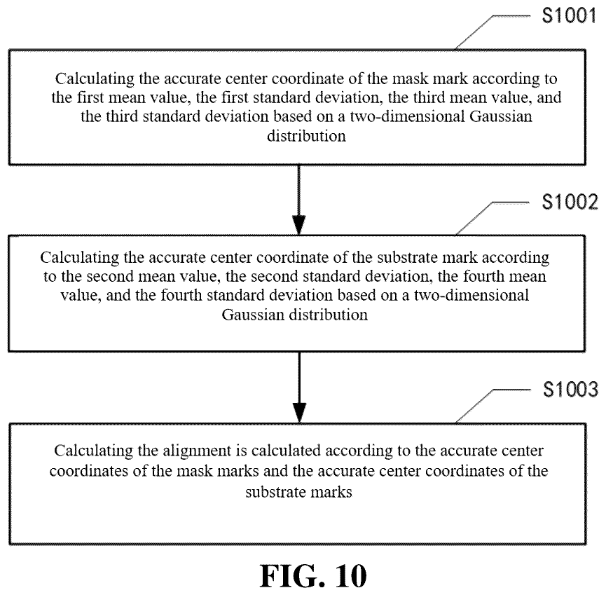

FIG. 10 schematically shows a flowchart of operation S105 provided in embodiments of the present disclosure.

As shown in FIG. 10, operation S105 of performing the statistical fusion on the first mean value, the first standard deviation, the second mean value, the second standard deviation, the third mean value, the third standard deviation, the fourth mean value, and the fourth standard deviation to calculate more accurate mark centers may include operations S1001 to S1003.

In operation S1001, based on a two-dimensional Gaussian distribution, the accurate center coordinate of the mask mark is calculated according to the first mean value, the first standard deviation, the third mean value, and the third standard deviation.

In operation S1002, based on a two-dimensional Gaussian distribution, the accurate center coordinate of the substrate mark is calculated according to the second mean value, the second standard deviation, the fourth mean value, and the fourth standard deviation.

In operation S1003, the alignment deviation is calculated according to the accurate center coordinates of the mask marks and the accurate center coordinates of the substrate marks.

Exemplarily, the mean values and the variances of the center coordinates of the mask mark and the substrate mark obtained by the above two methods may be expressed as two-dimensional Gaussian distributions, and the accurate center coordinate of the mask mark or the accurate center coordinate of the substrate mark may be calculated according to:

$$( {x}^{*} , {y}^{*} ) = {u}^{*} ( x , y ) = u 1 + \frac{{σ1}^{2} ( x , y ) ( u 2 ( x , y ) - u 1 ( x , y ) )}{{σ1}^{2} ( x , y ) + {σ2}^{2} ( x , y )}$$

where [u1(x,y), σ1(x,y)] represents the two-dimensional Gaussian distribution corresponding to the first mean value and the first standard deviation or the two-dimensional Gaussian distribution corresponding to the second mean value and the second standard deviation, and [u2(x,y), σ2(x,y)] represents the two-dimensional Gaussian distribution corresponding to the third mean value and the third standard deviation or the two-dimensional Gaussian distribution corresponding to the fourth mean value and the fourth standard deviation.

The alignment deviation is then calculated according to:

$$Δ x = \frac{( {x}_{w 1}^{*} - {x}_{m 1}^{*} ) + ( {x}_{w 2}^{*} - {x}_{m 2}^{*} )}{2}$$

$$Δ y = \frac{( {y}_{w 1}^{*} - {y}_{m 1}^{*} ) + ( {y}_{w 2}^{*} - {y}_{m 2}^{*} )}{2}$$

$$Δθ = arctan \frac{( {y}_{w 1}^{*} - {y}_{m 1}^{*} ) - ( {y}_{w 2}^{*} - {y}_{m 2}^{*} )}{D}$$

where the mask and the substrate each have two alignment marks, the accurate coordinates of the two alignment marks of the mask are respectively

$$( {x}_{m 1}^{*} , {y}_{m 1}^{*} ) , ( {x}_{m 2}^{*} , {y}_{m 2}^{*} ) ,$$

D is distance between the two alignment marks of the mask, the accurate coordinates of the two alignment marks of the substrate are respectively

$$( {x}_{w 1}^{*} , {y}_{w 1}^{*} ) , ( {x}_{w 2}^{*} , {y}_{w 2}^{*} ) ,$$

Δx is a horizontal distance deviation between the mask and the substrate, Δy is a vertical distance deviation between the mask and the substrate, and Δθ is a rotation angle deviation between the mask and the substrate.

Based on the calculated alignment deviation, the mask and the substrate may be aligned by moving Δx and Δy left and right and rotating Δθ.

It should be noted that the alignment method of the mask and the substrate described above is based on the alignment marks on the mask being square alignment marks and the alignment marks on the substrate being cross alignment marks. It should be understood that if the alignment mark on the mask is set to be a cross alignment mark and the alignment mark on the substrate is set to be a square alignment mark, the alignment method of the mask and the substrate described above may also be used for alignment. That is, when calculating a mean value and a standard deviation of center coordinates of the alignment mark on the mask, the calculation methods for the second mean value, the second standard deviation, the fourth mean value, and the fourth standard deviation are used, while when calculating a mean value and a standard deviation of center coordinates of the alignment mark on the substrate, the calculation methods for the first mean value, the first standard deviation, the third mean value, and the third standard deviation are used. Therefore, an alignment method with setting the alignment mark on the mask as a cross alignment mark and the alignment mark on the substrate as a square alignment mark also falls within the protection scope of the present disclosure.

The specific embodiments described above further elaborate on the objectives, technical solutions, and beneficial effects of the present disclosure. It should be understood that the above descriptions are only specific embodiments of the present disclosure and are not intended to limit the present disclosure. Any modifications, equivalent substitutions, improvements, etc., made within the spirit and principles of the present disclosure shall be included in the protection scope of the present disclosure.

1. An alignment method of a mask and a substrate, comprising:
summing grayscale values in a mark image row by row or column by column respectively, so as to obtain first projection summation curves corresponding to rows and second projection summation curves corresponding to columns;
calculating a first mean value and a first standard deviation of center coordinates of a mask mark, and a second mean value and a second standard deviation of center coordinates of a substrate mark based on the first projection summation curve corresponding to the rows and the second projection summation curve corresponding to the columns;
extracting image contours of the mark image, and adding a horizontal processing window or a vertical processing window to the image contours;
extracting a first contour grayscale curve of each row in the horizontal processing window or a second contour grayscale curve of each column in the vertical processing window;
calculating a third mean value and a third standard deviation of the center coordinates of the mask mark, and a fourth mean value and a fourth standard deviation of the center coordinates of the substrate mark according to the first contour grayscale curve of each row or the second contour grayscale curve of each column;
performing statistical fusion on the first mean value, the first standard deviation, the second mean value, the second standard deviation, the third mean value, the third standard deviation, the fourth mean value, and the fourth standard deviation to obtain an alignment deviation; and
aligning the mask and the substrate according to the alignment deviation.

2. The alignment method of the mask and the substrate according to claim 1, wherein calculating the first mean value and the first standard deviation of the center coordinates of the mask mark and the second mean value and the second standard deviation of the center coordinates of the substrate mark based on the first projection summation curve corresponding to the rows and the second projection summation curve corresponding to the columns comprises:
segmenting the first projection summation curve with a first grayscale threshold, and segmenting the second projection summation curve with a second grayscale threshold;
calculating a first centroid for each peak on the first projection summation curve whose value exceeds the first grayscale threshold, and calculating a second centroid for each peak on the second projection summation curve whose value exceeds the second grayscale threshold;
calculating a center coordinate of the mask mark and a center coordinate of the substrate mark according to the first centroid and the second centroid;
changing magnitudes of the first grayscale threshold and the second grayscale threshold, and repeating the above operations to obtain multiple center coordinates of the mask mark and multiple center coordinates of the substrate mark; and
calculating the first mean value and the first standard deviation according to the multiple center coordinates of the mask mark, and calculating the second mean value and the second standard deviation according to the multiple center coordinates of the substrate mark.

3. The alignment method of the mask and the substrate according to claim 2, wherein calculating the center coordinate of the mask mark and the center coordinate of the substrate mark according to the first centroid and the second centroid comprises:
determining y-coordinates corresponding to peaks above the first grayscale threshold on the first projection summation curve according to the first centroid;
determining x-coordinates corresponding to peaks above the second grayscale threshold on the second projection summation curve according to the second centroid; and
calculating the center coordinate of the mask mark and the center coordinate of the substrate mark according to the y-coordinates corresponding to the peaks and the x-coordinates corresponding to the peaks.

4. The alignment method of the mask and the substrate according to claim 3, wherein the first centroid or the second centroid gₖ(i) is calculated according to:
$${g}_{k} ( i ) = \frac{{\sum }_{x 1}^{x 2} ( S ( x ) \cdot x )}{{\sum }_{x 1}^{x 2} S ( x )}$$
where x is a row number or column number of a pixel in the mark image, S(x) is a sum of grayscale values of pixels in an x-th row or an x-th column, k is a serial number of a peak on the first projection summation curve whose peak value exceeds the first grayscale threshold or a serial number of a peak above the second grayscale threshold on the second projection summation curve, x1 and x2 are respectively a start coordinate and an end coordinate of a k-th peak after segmenting, and i is a number of changes in the first grayscale threshold or a number of changes in the second grayscale threshold.

5. The alignment method of the mask and the substrate according to claim 4, wherein a number of peaks above the first grayscale threshold on the first projection summation curve and a number of peaks above the second grayscale threshold on the second projection summation curve are both 3; and
calculating the center coordinate of the mask mark and the center coordinate of the substrate mark according to the y-coordinates corresponding to the peaks and the x-coordinates corresponding to the peaks comprises:
calculating an x-coordinate xₚ₁(i) and a y-coordinate yₚ₁(i) of the center coordinate of the mask mark, and an x-coordinate x_{q1}(i) and a y-coordinate y_{q1}(i) of the center coordinate of the substrate mark according to:
$${x}_{p 1} ( i ) = ( {x}_{g 1 ( i )} + {x}_{g 3 ( i )} ) / 2$$
$${y}_{p 1} ( i ) = ( {y}_{g 1 ( i )} + {y}_{g 3 ( i )} ) / 2$$
$${x}_{q 1} ( i ) = {x}_{g 2 ( i )}$$
$${y}_{q 1} ( i ) = {y}_{g 2 ( i )}$$
where p represents the mask, q represents the substrate, x_{g1}(i), x_{g2}(i), and x_{g3}(i) are respectively the x-coordinates corresponding to the peaks above the second grayscale threshold on the second projection summation curve, and y_{g1}(i), y_{g2}(i), and y_{g3}(i) are respectively the y-coordinates corresponding to the peaks above the first grayscale threshold on the first projection summation curve.

6. The alignment method of the mask and the substrate according to claim 1, wherein calculating the third mean value and the third standard deviation of the center coordinates of the mask mark and the fourth mean value and the fourth standard deviation of the center coordinates of the substrate mark according to the first contour grayscale curve of each row or the second contour grayscale curve of each column comprises:
performing interpolation on the first contour grayscale curve according to a first interpolation threshold or on the second contour grayscale curve according to a second interpolation threshold, so as to obtain coordinates of contour boundaries formed by the mask and the substrate on the first contour grayscale curve or on the second contour grayscale curve;
calculating the center coordinates of the mask mark and the center coordinates of the substrate mark corresponding to rows or columns according to the coordinates of the contour boundaries formed by the mask and the substrate on the first contour grayscale curve or on the second contour grayscale curve; and
calculating the third mean value, the third standard deviation, the fourth mean value, and the fourth standard deviation according to the center coordinates of the mask mark and the center coordinates of the substrate mark corresponding to the rows or the columns.

7. The alignment method of the mask and the substrate according to claim 6, wherein a number of grayscale peaks on the first contour grayscale curve of each row or a number of grayscale peaks on the second contour grayscale curve of each column is 6, wherein
calculating the center coordinates of the mask mark and the center coordinates of the substrate mark corresponding to the rows according to the coordinates of the contour boundaries formed by the mask and the substrate on the first contour grayscale curve comprises:
calculating an x-coordinate xₚ₂(j) of the center coordinate of the mask mark and an x-coordinate x_{q2}(j) of the center coordinate of the substrate mark that correspond to a j-th row of pixels in the horizontal processing window according to:
$${x}_{p 2} ( j ) = ( {Cx}_{j , 1} + {Cx}_{j , 2} + {Cx}_{j , 5} + {Cx}_{j , 6} ) / 4$$
$${x}_{q 2} ( j ) = ( {Cx}_{j , 3} + {Cx}_{j , 4} ) / 2$$
and a y-coordinate yₚ₂(j) of the center coordinate of the mask mark and a y-coordinate y_{q2}(j) of the center coordinate of the substrate mark are a y-coordinate of the j-th row of pixels on the first contour grayscale curve, which is able to be obtained by converting a row number of the pixels into a coordinate value, where y represents a serial number of a grayscale peak, taking an integer from 1 to 6, and Cx_{j,v} represents an x-coordinate after interpolation of a v-th grayscale peak corresponding to the j-th row of pixels, where Cx_{j,v}=(C_{jl,v}+C_{jr,v})/2; and
calculating the center coordinates of the mask mark and the center coordinates of the substrate mark corresponding to the columns according to the coordinates of the contour boundaries formed by the mask and the substrate on the second contour grayscale curve comprises:
calculating a y-coordinate yₚ₂(w) of the center coordinate of the mask mark and a y-coordinate y_{q2}(w) of the center coordinate of the substrate mark that correspond to a w-th column of pixels in the vertical processing window according to:
$${y}_{p 2} ( w ) = ( {Cy}_{w , 1} + {Cy}_{w , 2} + {Cy}_{w , 5} + {Cy}_{w , 6} ) / 4$$
$${y}_{q 2} ( w ) = ( {Cy}_{w , 3} + {Cy}_{w , 4} ) / 2$$
and an x-coordinate xₚ₂(w) of the center coordinate of the mask mark and an x-coordinate x_{q2}(w) of the center coordinate of the substrate mark are an x-coordinate of the w-th column of pixels on the second contour grayscale curve, which is able to be obtained by converting a column number of the pixels into a coordinate value, where v represents a serial number of a grayscale peak, taking an integer from 1 to 6, and Cy_{w,v} represents a y-coordinate after interpolation of a r-th grayscale peak corresponding to the w-th column of pixels, where Cy_{w,v}=(C_{wl,v}+C_{wr,v})/2.

8. The alignment method of the mask and the substrate according to claim 1, wherein performing the statistical fusion on the first mean value, the first standard deviation, the second mean value, the second standard deviation, the third mean value, the third standard deviation, the fourth mean value, and the fourth standard deviation to obtain the alignment deviation comprises:
calculating an accurate center coordinate of the mask mark according to the first mean value, the first standard deviation, the third mean value, and the third standard deviation based on a two-dimensional Gaussian distribution;
calculating an accurate center coordinate of the substrate mark according to the second mean value, the second standard deviation, the fourth mean value, and the fourth standard deviation based on a two-dimensional Gaussian distribution; and
calculating the alignment deviation according to accurate center coordinates of mask marks and accurate center coordinates of substrate marks.

9. The alignment method of the mask and the substrate according to claim 8, wherein the accurate center coordinate of the mask mark or the accurate center coordinate of the substrate mark is calculated according to:
$$( {x}^{*} , {y}^{*} ) = {u}^{*} ( x , y ) = u 1 + \frac{{σ1}^{2} ( x , y ) ( u 2 ( x , y ) - u 1 ( x , y ) )}{{σ1}^{2} ( x , y ) + {σ2}^{2} ( x , y )}$$
where [u1(x,y), σ1(x,y)] represents the two-dimensional Gaussian distribution corresponding to the first mean value and the first standard deviation or the two-dimensional Gaussian distribution corresponding to the second mean value and the second standard deviation, and [u2(x,y), σ2(x,y)] represents the two-dimensional Gaussian distribution corresponding to the third mean value and the third standard deviation or the two-dimensional Gaussian distribution corresponding to the fourth mean value and the fourth standard deviation.

10. The alignment method of the mask and the substrate according to claim 9, wherein calculating the alignment deviation according to the accurate center coordinates of the mask marks and the accurate center coordinates of the substrate marks comprises:
calculating the alignment deviation according to:
$$Δ x = \frac{( {x}_{w 1}^{*} - {x}_{m 1}^{*} ) + ( {x}_{w 2}^{*} - {x}_{m 2}^{*} )}{2}$$
$$Δ y = \frac{( {y}_{w 1}^{*} - {y}_{m 1}^{*} ) + ( {y}_{w 2}^{*} - {y}_{m 2}^{*} )}{2}$$
$$Δθ = arctan \frac{( {y}_{w 1}^{*} - {y}_{m 1}^{*} ) - ( {y}_{w 2}^{*} - {y}_{m 2}^{*} )}{D}$$
where the mask and the substrate each have two alignment marks, accurate coordinates of the two alignment marks of the mask are respectively
$$( {x}_{m 1}^{*} , {y}_{m 1}^{*} ) , ( {x}_{m 2}^{*} , {y}_{m 2}^{*} ) ,$$
D is a distance between the two alignment marks of the mask, accurate coordinates of the two alignment marks of the substrate are respectively
$$( {x}_{w 1}^{*} , {y}_{w 1}^{*} ) , ( {x}_{w 2}^{*} , {y}_{w 2}^{*} ) ,$$
Δx is a horizontal distance deviation between the mask and the substrate, Δy is a vertical distance deviation between the mask and the substrate, and Δθ is a rotation angle deviation between the mask and the substrate.
